(19) United States
(12) Patent Application Publication
(10) Pub. No.: US 2025/0183172 A1
(43) Pub. Date: Jun. 5, 2025

(54) CHANNEL ISOLATION FOR A LOW-POWER SEMICONDUCTOR DEVICE

(71) Applicant: International Business Machines Corporation, Armonk, NY (US)

(72) Inventors: Min Gyu Sung, Latham, NY (US); Tao Li, Slingerlands, NY (US); Ruilong Xie, Niskayuna, NY (US); Eric Miller, Albany, NY (US)

(21) Appl. No.: 18/528,917

(22) Filed: Dec. 5, 2023

(51) Int. Cl. H01L 23/528; H01L 29/06; H01L 29/40; H01L 29/417; H01L 29/423; H01L 29/66; H01L 29/775

(52) U.S. Cl. CPC H01L 23/5286; H10D 30/014; H10D 30/43; H10D 30/6729; H10D 30/6735; H10D 62/121; H10D 64/01

(57) ABSTRACT

A semiconductor chip with at least one low-power nanosheet gate-all-around field-effect transistor with a backside contact and a high-performance nanosheet gate-all-around field-effect transistor. The low-power gate-all-around field-effect transistor has a source/drain electrically isolated from at least a bottom nanosheet channel. The high-performance gate-all-around field-effect transistor with a source/drain contacting each of the plurality of nanosheet channels. The low-power nanosheet gate-all-around field semiconductor device includes a dielectric material electrically isolating at least the bottom channel from a backside contact and the source/drain. The high-performance nanosheet gate-all-around field-effect transistor includes a backside contact contacting at least the source/drain, the dielectric material, inner gate spacers, and a backside power rail. The backside contact of the low-power nanosheet gate-all-around field-effect transistor and the high-performance nanosheet gate-all-around field-effect transistor contacts a backside power rail connecting to a backside power delivery network.

### BACKGROUND

The disclosure generally relates to forming a semiconductor device and more particularly, to nanosheet field-effect transistors with backside channel depopulation using dielectric inner spacers contacting backside contacts.

The amount of data we process is rapidly increasing at a rate higher than that of Moore's law. Increasing system performance requirements, driven at least in part by the increasing use of artificial intelligence, continue to drive tighter pitches in semiconductor devices and smaller semiconductor chips. For logic scaling at the two-nanometer node, planar and non-planar semiconductor device structures, such as metal-oxide-semiconductor field-effect transistors (MOSFETs), must be scaled to smaller dimensions.

With the evolution of reduced-size transistors, semiconductor technology has progressed from planar transistor designs to three-dimensional type finFET designs which are further evolving into gate-all-around transistor designs. With increasing demands to reduce the dimensions of transistor devices, nanosheet field-effect transistors (FETs) help achieve a reduced device footprint while maintaining device performance. A nanosheet FET device contains one or more portions of layers of semiconductor channel material having a vertical thickness that is substantially less than its width. A typical nanosheet FET includes a plurality of stacked nanosheets extending between a pair of source/drain epitaxial regions. The nanosheet FET device may be a gate-all-around device in which a gate surrounds the channels of the nanosheet FET devices. Utilizing stacked nanosheets, Gate-All-Around nanosheet field-effect transistors (GAA nanosheet FETs) and 3D-stacked complementary metal-oxide semiconductor (CMOS) devices such as complementary field-effect transistor devices will be key to continuing to extend beyond Moore's Law.

GAA nanosheet FET devices can provide high drive currents due to wide effective channel width (Weff) while maintaining short-channel control. However, in many cases, backside power delivery networks need to be coupled with GAA nanosheet FETs for performance and back-end-of-line (BEOL) wiring congestion issues. As the semiconductor industry continues to drive to the two-nanometer technology node with tighter pitches and increasing performance, increased use of backside interconnect layers for a backside power delivery network is emerging. Creating backside interconnect layers below the front-end-of-line semiconductor devices provides improved power performance and more routing options for semiconductor devices relieving some of the BEOL wiring congestion. A backside power delivery network improves semiconductor device gate delay and reduces BEOL wiring congestion.

### SUMMARY

The following presents a summary to provide a basic understanding of one or more embodiments of the disclosure. This summary is not intended to identify key elements or delineate any scope of the particular embodiments or any scope of the claims.

Aspects of the disclosed invention relate to a semiconductor structure for a low-power nanosheet gate-all-around field-effect transistor with a dielectric material between and contacting a backside contact and at least a bottom channel of the nanosheet gate-all-around field-effect transistor. The dielectric material is between the backside contact and at least the bottom channel of a plurality of channels in the semiconductor structure.

Aspects of the disclosed invention relate to a semiconductor structure of a semiconductor chip with at least one low-power nanosheet gate-all-around field-effect transistor and at least one high-performance nanosheet gate-all-around field-effect transistor. The low-power nanosheet gate-all-around field semiconductor device includes at least one source/drain and a backside contact that are electrically isolated from at least one bottom channel of a plurality of nanosheet channels. The high-performance nanosheet gate-all-around field-effect transistor includes source/drains where each source/drain contacts each channel of the high-performance nanosheet gate-all-around field-effect transistor.

Aspects of the disclosed invention include a method of forming a low-power nanosheet gate-all-around transistor by electrically isolating one or more channels of the plurality of channels in a nanosheet gate-all-around transistor with a dielectric material between the backside contact and a portion of at least one channel of the plurality of channels. The method forming a portion of the nanosheet gate-all-around transistor with a carrier wafer bonded to frontside interconnect wiring and a bottom dielectric layer using known nanosheet semiconductor manufacturing processes, where the nanosheet gate-all-around transistor includes a backside interlayer dielectric material with a placeholder in the backside interlayer dielectric layer.

The method includes removing a portion of the backside interlayer dielectric around a portion of the placeholder and then, removing the placeholder, where removing the placeholder includes removing a bottom portion of a source/drain contacting the placeholder. The method includes performing an isotropic etch of exposed portions of the source/drain, where the isotropic etch exposes a sidewall of at least one channel of a plurality of channels in the nanosheet gate-all-around transistor.

The method includes laterally etching a portion of the at least one channel, where the lateral etch extends horizontally to an area between portions of a gate structure of the nanosheet gate-all-around transistor and then, depositing a dielectric material replacing the removed portion of the at least one channel.

The method includes forming a backside contact that is electrically isolated from the at least one channel by the dielectric material and then, forming a backside power rail contacting the backside interlayer dielectric and the backside contact. In embodiments, the method of forming the low-power nanosheet gate-all-around transistor includes forming, in the same semiconductor chip as the low-power nanosheet gate-all-around transistor, a high-performance nanosheet gate-all-around transistor with the source/drain and the backside contact electrically connected to each of the plurality of channels.

### BRIEF DESCRIPTION OF THE DRAWINGS

The above and other aspects, features, and advantages of various embodiments of the present invention will be more apparent from the following description taken in conjunction with the accompanying drawings.

FIG. 1A depicts a top view of an illustration of a semiconductor design of a high-performance device, in accordance with an embodiment of the present invention.

FIG. 1B depicts a top view of an illustration of a semiconductor design of a low-power device, in accordance with an embodiment of the present invention.

FIGS. 2A and 2B depict cross-sectional views of a high-performance semiconductor device structure and a low-power semiconductor device structure, respectively, after forming GAA FET devices on a semiconductor layer with placeholders and a carrier wafer, in accordance with an embodiment of the present invention.

FIGS. 3A and 3B depict cross-sectional views of the semiconductor structures after removing a semiconductor substrate, in accordance with an embodiment of the present invention.

FIGS. 4A and 4B depict cross-sectional views of the semiconductor structures after removing an etch stop layer, removing a semiconductor material layer, and depositing a backside interlayer dielectric, in accordance with an embodiment of the present invention.

FIGS. 5A and 5B depict cross-sectional views of the semiconductor structures after depositing and patterning an optical planarization layer (OPL), and then, removing the exposed portions of the backside interlayer dielectric (BILD), in accordance with an embodiment of the present invention.

FIGS. 6A and 6B depict cross-sectional views of the semiconductor structures after removing the exposed placeholders and portions of the S/D under the removed placeholders, in accordance with an embodiment of the present invention.

FIGS. 7A and 7B depict cross-sectional views of the semiconductor structures after depositing another layer of OPL on the BILD, exposing a bottom portion of the S/D, performing an isotropic etch on the S/D and then, using a lateral etch process removing a bottom channel exposed by the removed portion of the S/D, in accordance with an embodiment of the present invention.

FIGS. 8A and 8B depict cross-sectional views of the semiconductor structures after depositing a dielectric material in the opening created by the removal of the channel, in accordance with an embodiment of the present invention.

FIGS. 9A and 9B depict cross-sectional views of the semiconductor structures after OPL removal and forming the backside contacts, in accordance with an embodiment of the present invention.

FIGS. 10A and 10B depict cross-sectional views of the semiconductor structures after depositing a backside power rail (BPR) and backside interconnect wiring, in accordance with an embodiment of the present invention.

### DETAILED DESCRIPTION

Embodiments of the present invention recognize that for some semiconductor chip designs it is sometimes advantageous to integrate one or more low-power semiconductor devices with one or more high-performance nanosheet semiconductor devices. One approach to integrating a low-power nanosheet semiconductor device with a high-performance nanosheet semiconductor device is to use channel de-population in the low-power nanosheet semiconductor device. Removing one or more active nanosheet-based channels reduces the power required by the semiconductor device to create the low-power nanosheet semiconductor device. Depopulating the active channels in a nanosheet semiconductor device such as a nanosheet gate-all-around field-effect transistor (GAA FET), can provide a different level of power for the nanosheet semiconductor device. For example, a high-performance nanosheet semiconductor device performs more effectively with a higher number of active channels and a low-performance nanosheet semiconductor device performs more effectively with a lower number of active channels. With the right combination of high-performance nanosheet semiconductor devices and low-performance nanosheet semiconductor devices such as static random-access memory (SRAM) formed using nanosheet technology, it is possible to achieve better electrical functionality in the semiconductor chip.

Reducing the number of active channels in the low-power nanosheet semiconductor device compared to the high-performance nanosheet semiconductor device can provide the effective integration of a low-power nanosheet semiconductor device with one or more high-performance nanosheet semiconductor devices.

Aspects of the present invention provide at least one low-power nanosheet semiconductor device that can be formed concurrently with one or more high-performance nanosheet semiconductor devices. The low-power nanosheet semiconductor device includes at least one dielectric material creating an inner spacer between the backside contact and at least one bottom channel of the nanosheet channels in the semiconductor device. The dielectric material electrically isolates at least the bottom channel of the low-power nanosheet semiconductor device from the backside contact. The dielectric inner spacer that electrically isolates at least the bottom or lowest channel from the backside contact de-populates the bottom channel of the low-power nanosheet semiconductor device. In embodiments of the present invention, the low-power nanosheet semiconductor device can be a nanosheet gate-all-around field effect transistor (GAA FET). In some embodiments, the low-power GAA FET is a bottom GAA FET in one or more stacked GAA FETs.

In embodiments, the backside contact contacts at least the bottom inner gate spacer, at least one portion of the dielectric material replacing the removed channels such as the bottom channel of the nanosheet field-effect transistor and extends above at least the top surface of the top removed channel of the field-effect transistor to contact the source/drain. In embodiments, the source/drain contacts at least one channel of the low-power nanosheet gate-all-around field-effect transistor.

In various embodiments, the backside contact contacts at least the bottom inner gate spacer, the dielectric material replacing the removed bottom channel, and a rounded, upside-down u-shaped, bottom surface of the source/drain. In the low-power GAA FET, the backside contact also contacts a backside power rail above the backside interconnect wiring layers, a bottom interlayer dielectric, and a bottom dielectric isolation.

In embodiments of the present invention, the low-power nanosheet semiconductor device can have “n” number of nanosheet channels and the dielectric material creating the inner spacer electrically isolating channels from the backside contact can be present contacting any number of channels up to a maximum of “n−1” channels in the low-power nanosheet semiconductor device. The dielectric material contacts the backside contact and the remaining portion of the electrically isolated channel or channels. Using the dielectric contact as an inner spacer preventing the contact of one or more nanosheet channels with the backside contact effectively depopulates one or more channels of the nanosheet channels to form a low-power nanosheet semiconductor device.

Embodiments of the present invention include a method to electrically isolate at least one channel of a GAA FET to create a low-power nanosheet semiconductor device. The method includes using known semiconductor manufacturing processes to form a first semiconductor structure with one or more nanosheet GAA FET devices on a semiconductor substrate with an etch stop layer and a layer of semiconductor material with semiconductor placeholders contacting the source/drains of the nanosheet GAA FETs. The nanosheet GAA FETs have at least one contact connecting to the frontside interconnect wiring where the frontside interconnect wiring is bonded to a carrier wafer.

The method includes flipping the wafer and removing the semiconductor substrate, then removing the etch stop layer, followed by the removal of the semiconductor layer from the first semiconductor structure. After removing the semiconductor layer, a layer of backside interlayer dielectric (BILD) is deposited over the exposed surfaces of the placeholder and, a bottom dielectric isolation under the nanosheet GAA FETs to form a second semiconductor structure. The method includes patterning the BILD and selectively removing portions of the BILD to expose a bottom portion of at least one placeholder under the second semiconductor structure. An etch process removes the exposed placeholder and a bottom portion of the source/drain (S/D). A lateral isotropic etch removes exposed portions of at least one channel exposed by the removal of the portion of the S/D. Using a known dielectric material deposition process, an inner spacer can be formed in the opening formed by the removal of the channel. The dielectric material electrically isolates the remaining portion of the channel from the opening or trench created by the S/D etching process.

Using known backside contact formation processes, a contact metal is deposited in the opening and a chemical-mechanical polish (CMP) occurs. The backside contact connects with one or more nanosheet channels and one or more inner spacers formed with the dielectric material. A backside power rail is deposited on the exposed surfaces of the BILD and the backside contact. Using known back-end-of-line (BEOL) processes, forming one or more layers of backside interconnect wiring on the backside power rail occurs.

The low-power semiconductor device such as a low-power nanosheet GAA FET can be formed simultaneously with another nanosheet semiconductor device such as one or more high-performance nanosheet GAA FETs in a semiconductor chip. The high-performance nanosheet GAA FETs can have all of the active channels in the nanosheet stack connecting to the backside contacts while the low-power nanosheet GAA FET formed with a similar or the same nanosheet stack has one or more less active channels connected to the backside contact. In this way, a low-power nanosheet semiconductor device with at least one channel that is electrically isolated or de-populated in the nanosheet semiconductor device is presented in embodiments of the present invention. In these embodiments, a high-performance nanosheet semiconductor can have at least one more active channel electrically connecting to the backside contact than the low-power nanosheet semiconductor device.

The following description with reference to the accompanying drawings is provided to assist in a comprehensive understanding of exemplary embodiments of the invention as defined by the claims and their equivalents. It includes various specific details to assist in that understanding but these are to be regarded as merely exemplary. Accordingly, those of ordinary skill in the art will recognize that various changes and modifications of the embodiments described herein can be made without departing from the scope and spirit of the invention. Some of the process steps, depicted, can be combined as an integrated process step. In addition, descriptions of well-known functions and constructions may be omitted for clarity and conciseness.

The terms and words used in the following description and claims are not limited to the bibliographical meanings and are merely used to enable a clear and consistent understanding of the invention. Accordingly, it should be apparent to those skilled in the art that the following description of exemplary embodiments of the present invention is provided for illustration purposes only and not for the purpose of limiting the invention as defined by the appended claims and their equivalents.

It is to be understood that the singular forms “a,” “an,” and “the” include plural referents unless the context dictates otherwise. Thus, for example, reference to “a component surface” includes reference to one or more of such surfaces unless the context dictates otherwise.

For purposes of the description hereinafter, terms such as “upper”, “lower”, “right”, “left”, “vertical”, “horizontal”, “top”, “bottom”, and derivatives thereof shall relate to the disclosed structures and methods, as oriented in the drawing figures. Terms such as “above”, “on”, “overlying”, “atop”, “on top”, “positioned on” or “positioned atop” mean that a first element, such as a first structure, is present on a second element, such as a second structure, wherein intervening elements, such as an interface structure may be present between the first element and the second element. The term “direct contact” or “contact” means that a first element, such as a first structure, and a second element, such as a second structure, are connected without any intermediary conducting, insulating, or semiconductor layers at the interface of the two elements.

In the interest of not obscuring the presentation of embodiments of the present invention, in the following detailed description, some processing steps or operations that are known in the art may have been combined for presentation and for illustration purposes and in some instances may have not been described in detail. In other instances, some processing steps or operations that are known in the art may not be described at all. It should be understood that the following description is rather focused on the distinctive features or elements of various embodiments of the present invention.

Detailed embodiments of the claimed structures and methods are disclosed herein. The method steps described below do not form a complete process flow for manufacturing integrated circuits on semiconductor chips. The present embodiments can be practiced in conjunction with the integrated circuit fabrication techniques for semiconductor chips and devices currently used in the art, and only so much of the commonly practiced process steps are included as are necessary for an understanding of the described embodiments. The figures represent cross-section portions of a semiconductor chip or a substrate, such as a semiconductor wafer during fabrication, and are not drawn to scale, but instead are drawn to illustrate the features of the described embodiments. Specific structural and functional details disclosed herein are not to be interpreted as limiting, but merely as a representative basis for teaching one skilled in the art to variously employ the methods and structures of the present disclosure. In the description, details of well-known features and techniques may be omitted to avoid unnecessarily obscuring the presented embodiments.

References in the specification to “one embodiment”, “other embodiment”, “another embodiment”, “an embodiment,” etc., indicate that the embodiment described may include a particular feature, structure or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is understood that it is within the knowledge of one skilled in the art to affect such feature, structure, or characteristic in connection with other embodiments whether or not explicitly described.

Reference will now be made in detail to the embodiments of the present invention, examples of which are illustrated in the accompanying drawings, wherein like reference numerals refer to like elements throughout.

Deposition processes for materials, such as metal materials, dielectric materials, and sacrificial materials include but are not limited to chemical vapor deposition (CVD), physical vapor deposition (PVD), atomic layer deposition (ALD), molecular layer deposition (MLD), high-density plasma (HDP) deposition, or gas cluster ion beam (GCIB) deposition. Variations of CVD processes include but are not limited to, atmospheric pressure CVD (APCVD), low-pressure CVD (LPCVD), plasma enhanced CVD (PECVD), and metal-organic CVD (MOCVD), and combinations thereof may also be employed.

Removal, removing, or etching as used herein includes but is not limited to patterning using one of lithography, photolithography, an extreme ultraviolet (EUV) lithography process, or any other known semiconductor patterning process followed by one or more etching processes. Some examples of etching processes include but are not limited to the following processes, such as a dry etching process using a reactive ion etch (RIE) or ion beam etch (IBE), a wet chemical etch process, or a combination of these etching processes.

It should also be understood that material compounds may be described in terms of listed elements, e.g., SiGe. These compounds include different proportions of the elements within the compound, e.g., SiGe includes SixGe₁₋ₓ where x is less than 1. In addition, other elements can be included in the compound and still function in accordance with the present principles.

Reference is now made to the figures. The figures provide schematic cross-sectional illustrations of semiconductor devices at intermediate stages of fabrication, according to one or more embodiments of the invention. The device provides schematic representations of the devices of the invention and is not to be considered accurate or limiting with regard to device element scale.

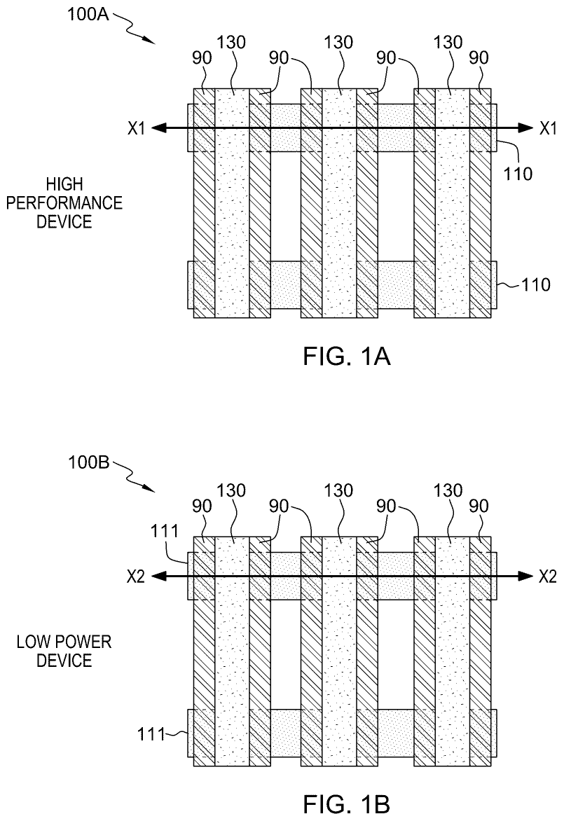

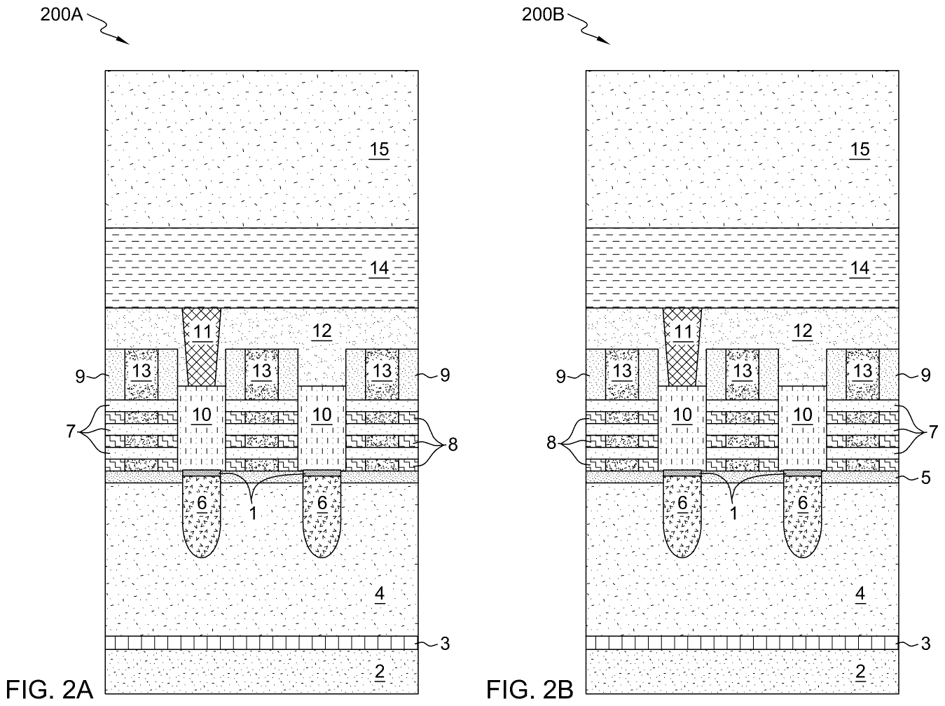

FIG. 1A depicts a top view of an illustration of semiconductor design 100A of a high-performance device, in accordance with an embodiment of the present invention. As depicted, FIG. 1A includes gate 130, gate spacers 90, and active region 110. Also, depicted in FIG. 1A is an illustration of a location of the X1-X1 cross-sections depicted later in FIGs. denoted with an “A” such as FIGS. 2A-10A (i.e., the FIGs. with an “A” are a cross-section through X1-X1 of FIG. 1A).

FIG. 1A is an illustration of the top view of semiconductor design 100A which is an example of a top view of a nanosheet high-performance semiconductor design utilized in embodiments of the present invention, as known to one skilled in the art, other semiconductor designs, not illustrated, can utilize the techniques presented in embodiments of the present invention and the method of forming a high-performance semiconductor device is not limited the specific semiconductor design 100A (i.e., other semiconductor designs using other types of semiconductor devices such as SRAMs).

FIG. 1B depicts a top view of an illustration of semiconductor design 100B of a low-power device, in accordance with an embodiment of the present invention. FIG. 1B includes gate 130, gate spacers 90, and active region 111. Also, depicted in FIG. 1B is an illustration of the location of the X2-X2 cross-sections depicted later in FIGS. 2B-10B (i.e., FIGs. with “B” such as FIG. 2B are cross-sections through X2-X2 of FIG. 1B).

FIG. 1B is an illustration of the top view of semiconductor design 100B which is one example of a top view of a low-power nanosheet semiconductor design utilized in embodiments of the present invention, as known to one skilled in the art, other semiconductor designs, not illustrated, can utilize the techniques presented in embodiments of the present invention and the method of forming a low-power semiconductor device. The low-power semiconductor device design is not limited to the specific semiconductor design 100B.

In various embodiments, semiconductor design 100A and semiconductor design 100B reside on the same semiconductor chip.

FIGS. 2A and 2B depict the cross-sectional views of semiconductor structure 200A and semiconductor structure 200B, respectively, after forming GAA FET devices on semiconductor layer 4 with placeholders 6 and carrier wafer 15, in accordance with an embodiment of the present invention. As depicted, FIG. 2A and FIG. 2B have the same semiconductor structure that can be a nanosheet GAA FET structure for three nanosheet GAA FETS as known to one skilled in the art. The known nanosheet GAA FET structure, as depicted, includes substrate 2, etch stop layer 3, semiconductor layer 4, placeholders 6, bottom dielectric isolation (BDI) 5, with three GAA FETs formed on protective layer 1, contacts 11 in ILD 12 connect the GAA FETs to frontside interconnect wiring 14 which is bonded to carrier wafer 15. Each of the GAA FETs includes at least channels 7, inner spacers 8, gate 13, gate spacers 9, and S/D 10. In various embodiments, protective layer 1 is a layer of silicon but in other embodiments, protective layer 1 can be composed of another semiconductor material. In various embodiments, placeholders 6 can be composed of silicon and germanium (e.g., SiGe).

The three GAA FETs are formed using known nanosheet semiconductor manufacturing processes using any number of nanosheet layers in a nanosheet stack. In other embodiments, more than three channels 7 can be present in semiconductor structures 200A and semiconductor structure 200B. In one embodiment, only two of channels 7 are present in the nanosheet stack forming the semiconductor structure. As discussed above with reference to FIGS. 1A and 1B, semiconductor structures 200A and 200B may reside on the same wafer or semiconductor substrate.

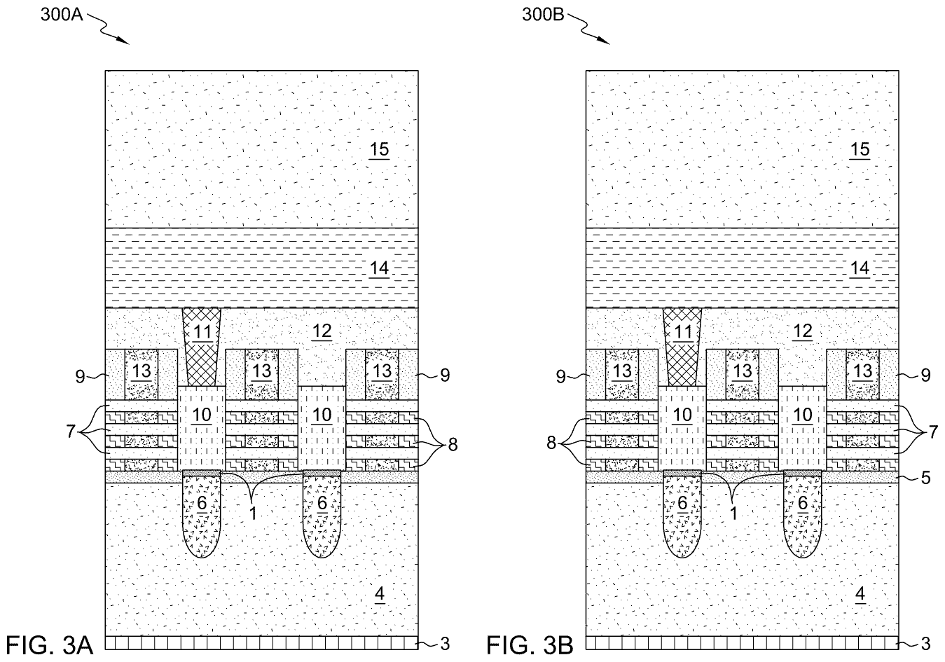

FIGS. 3A and 3B depict the cross-sectional views of semiconductor structure 300A and semiconductor structure 300B, respectively, after flipping the wafer and removing semiconductor substrate 2, in accordance with an embodiment of the present invention. As depicted, semiconductor structure 300A and semiconductor structure 300B are the same and include the elements of semiconductor structure 200A and semiconductor structure 200B without substrate 2.

A wafer flip is performed on semiconductor structures 200A and 200B, exposing the surface of substrate 2 as a top surface of the semiconductor structure before wafer grinding. For the purposes of the present invention, semiconductor structures 300A and 300B along with the following semiconductor structures up to and including semiconductor structures 1000A and 1000B are not depicted as flipped (i.e., carrier wafer 20 is depicted as the top surface of semiconductor structures 300A and 300B).

As depicted, FIG. 3A and FIGS. 3B, the semiconductor structures are depicted without illustrating the flipped wafer. In other words, the bottom surface of semiconductor substrate 2 as depicted in FIGS. 3A and 3B would be the top surface of the flipped wafer structure. FIGS. 3A-10A and FIGS. 3B-10B depict the semiconductor structures as not flipped (i.e., with carrier wafer 15 as the top portion or surface of the semiconductor structures). As depicted, the following methods and structures of the present invention are discussed as unflipped wafers but as known to one skilled in the art, the semiconductor processes discussed and resulting semiconductor structures are typically formed as flipped wafers.

After the wafer flip, substrate 2 can be removed using one or more of a known wafer grinding process and/or a wet semiconductor etching process. Substrate 2 may be composed of any semiconductor substrate material. In various embodiments, substrate 2 is silicon. After removing substrate 2, the bottom surface of etch stop layer 3 is exposed.

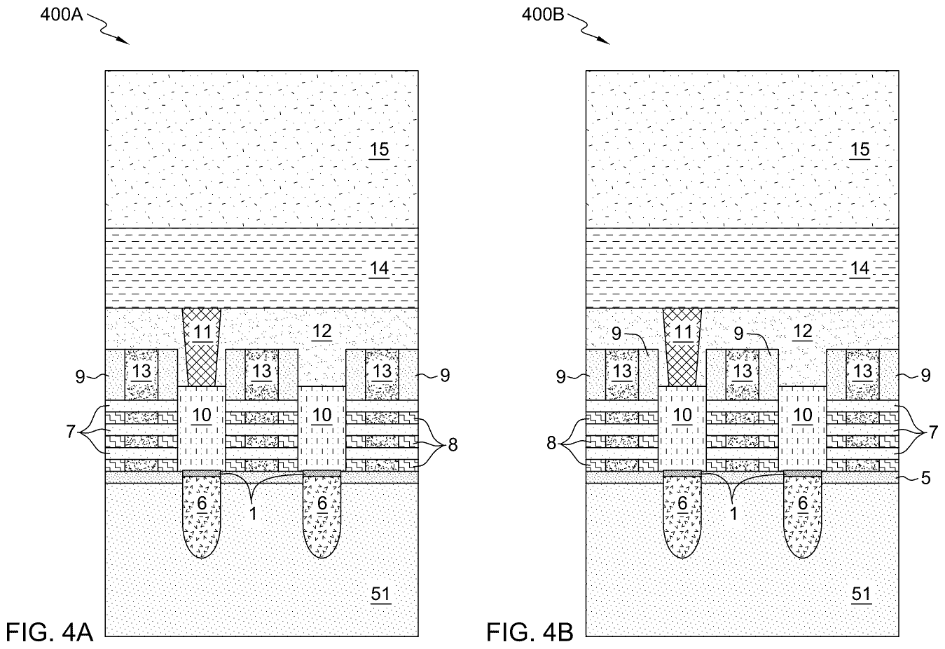

FIGS. 4A and 4B depict the cross-sectional views of semiconductor structure 400A and semiconductor structure 400B after removing etch stop layer 3, removing semiconductor layer 4, and depositing BILD 51, in accordance with an embodiment of the present invention. As depicted, semiconductor structures 400A and 400B are the same and include the elements of semiconductor structures 300A and 300B without etch stop layer 3, without semiconductor layer 4, and with BILD 51.

Etch stop layer 3 can be composed of any etch stop material used in etch stop layers for nanosheet GAA FET device formation. In various embodiments, etch stop layer 3 is composed of a silicon-germanium material. In some examples, etch stop layer 3 can be removed using a selective dry etching process.

Semiconductor layer 4 can be composed of any semiconductor material. In various embodiments, semiconductor layer 4 is composed of silicon. For example, semiconductor layer 4 can be removed using one or more known wet or dry semiconductor etching processes. After removing semiconductor layer 4, placeholders 6 and BDI 5 are exposed.

A layer of dielectric material is deposited over the exposed surfaces of placeholders 6 and BDI 5 forming a backside interlay dielectric (i.e., BILD 51). After depositing BILD 51, a CMP can be performed.

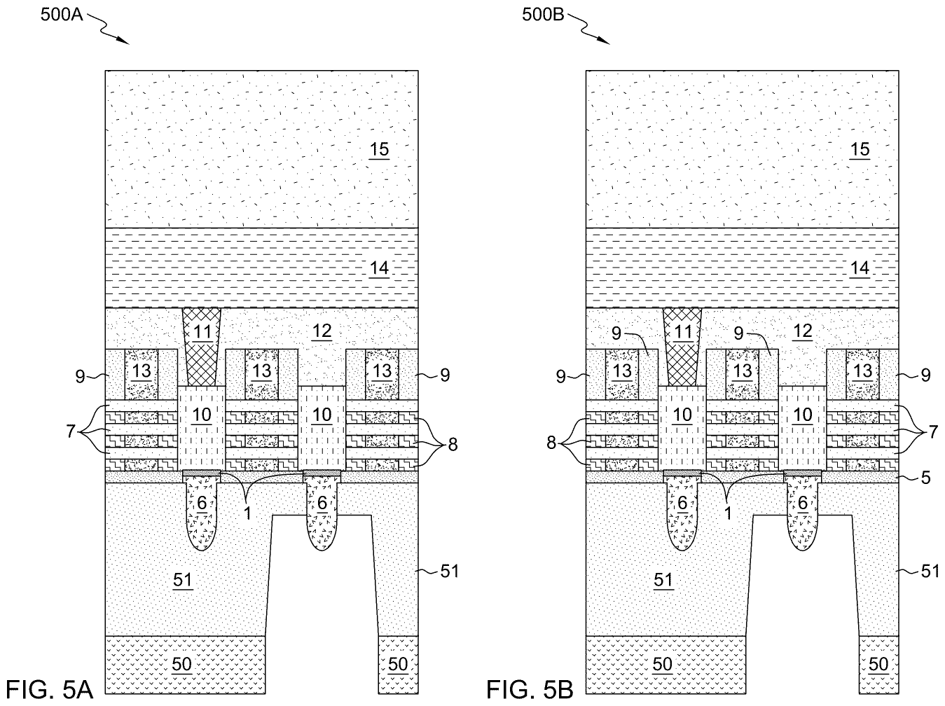

FIGS. 5A and 5B depict cross-sectional views of semiconductor structure 500A and semiconductor structure 500B after patterning OPL 50 and removing portions of BILD 51 and OPL 50, in accordance with an embodiment of the present invention. As depicted, semiconductor structure 500A and semiconductor structure 500B are the same and include the elements of semiconductor structure 400A and 400B with OPL 50 and without a portion of BILD 51 and OPL 50.

After depositing and patterning OPL 50, portions of OPL 50 and BILD 51 above one of placeholders 6 can be removed. As depicted in FIG. 5A and FIG. 5B, the bottom portion of one of the placeholders 6 is exposed by the removal of BILD 51.

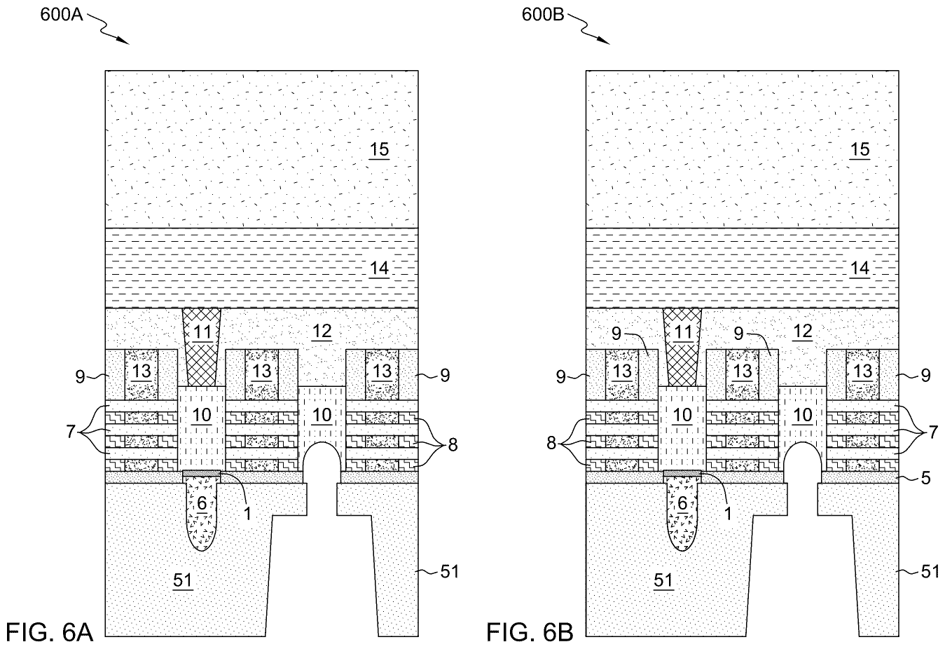

FIGS. 6A and 6B depict the cross-sectional views of semiconductor structure 600A and semiconductor structure 600B after removing the exposed placeholder 6 and portions of S/D 10 under the removed placeholder 6, in accordance with an embodiment of the present invention. As depicted, semiconductor structure 600A and semiconductor structure 600B are the same and include the elements of semiconductor structures 500A and 500B without the exposed placeholder 6, protective layer 1 above the removed placeholder 6, and without OPL 50 and an exposed portion of S/D 10 above protective layer 1.

In some cases, using a known one or more known OPL removal processes (e.g., OPL ash), OPL 50 can be removed before removing the portion of placeholder 6 and S/D 10. For example, a selective dry etching process can remove the remaining bottom portion of the exposed placeholder 6 and protective layer 1. Protective layer 1 can be a thin, interfacial semiconductor layer. In various embodiments, protective layer 1 is silicon.

A non-selective dry etching process such as a reactive ion etch (RIE) can occur to remove a portion of the exposed S/D 10. As depicted, in FIGS. 6A and 6B, the portion of S/D 10 exposed by the removal of protective layer 1 can be etched to a level approximately equal to the top of the bottom channel of channels 7. The etch of S/D 10 extends until the trench or etched opening in S/D 10 is about level with the top of the bottom channel of channels 7. In FIGS. 6A and 6B, the bottom channel of channels 7 is the closest channel to BDI 5. In other examples, the portion of S/D 10 removed in semiconductor structures 600A and 600B can be greater. In other examples, the etch of S/D 10 extends until the trench or opening is level with about the top of the second or middle channel of channels 7.

In general, the number of channels 7 can be illustrated as “n” number of channels 7. In FIGS. 6A and 6B, the trench or opening etched in S/D 10 extends to a depth that is at least equal to the top surface of the n−1 channels or less (e.g., n−1, n−2, n−3, and so on depending on the value of n) of channels 7. As depicted in FIGS. 6A and 6B, there are three of channels 7 and the etched opening extends above the top of the bottom channels of channels 7 and below the bottom of the middle channel of channels 7.

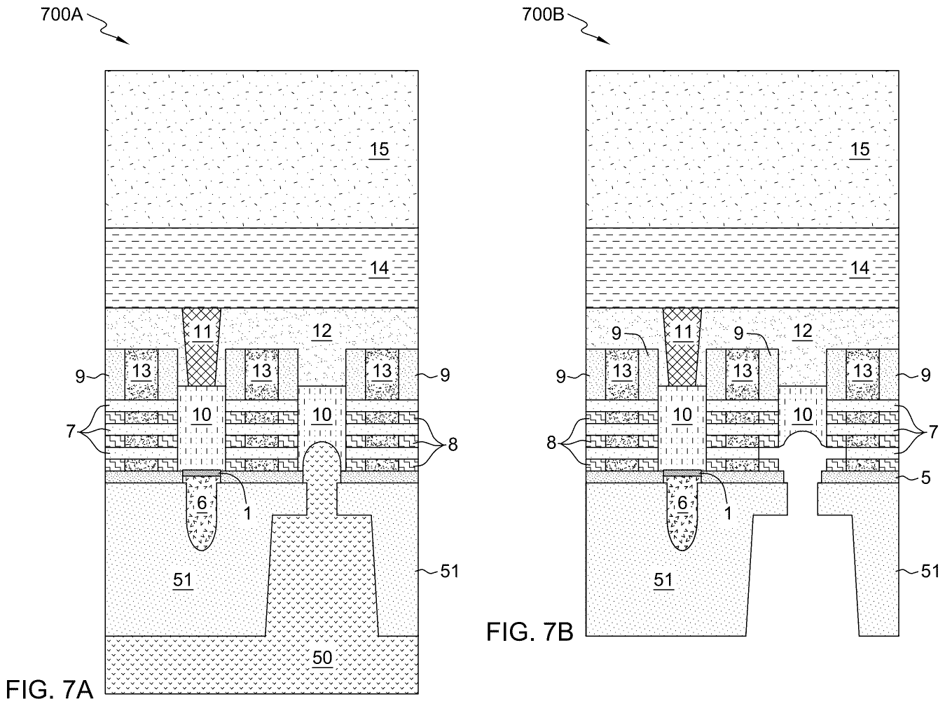

FIGS. 7A and 7B depict cross-sectional views of the semiconductor structures after depositing another layer of OPL 50 on BILD 111, exposing a bottom portion of at least one of S/D 10, performing an isotropic etch on the at least one of S/D 10 and then, using a lateral etch process removing any bottom channel exposed by the removed portion of S/D 10, in accordance with an embodiment of the present invention.

As depicted, FIG. 7A is a cross-sectional view X1-X1 of semiconductor structure 700A after depositing OPL 50 on BILD 51 and in the cavity exposing a bottom portion of S/D 10, in accordance with an embodiment of the present invention. As known to one skilled in the art, more than one S/D 10 can be exposed in other embodiments of the present invention. FIG. 7A includes the elements of semiconductor structure 600A with OPL 50. Using known OLP deposition methods such as spin coating, OPL 50 can be deposited in the opening depicted in FIG. 6A. OPL 50 can contact the sides of BILD 51, BDI 5, and exposed portions of the rightmost S/D 10.

FIG. 7B depicts cross-sectional view X2-X2 of semiconductor structure 700B after performing an isotropic etch on at least the rightmost of S/D 10 and then, a lateral etch process removing an outside portion of at least one of bottom channel of channels 7. As known to one skilled in the art, more than one of S/D 10 can be etched with an isotropic etching process. As depicted, FIG. 7B includes the elements of semiconductor structure 600B with an additional portion of one of S/D 10 removed and without the outer portion of the bottom channel of channels 7. The removed outer portion of the bottom channel is directly adjacent to the opening created during the isotropic etch of rightmost S/D 10.

An isotropic etch of S/D 10, for example, using a dry etching process, removes additional portions of S/D 10 and exposes an outer edge or surface of the bottom channel of channels 7. As depicted in FIG. 7B, after the removal of portions of S/D 10, the top surface of the opening in S/D 10 is below at least the bottom surface of the middle channel of channels 7 and is above the top surface of the bottom channel. In another example (not depicted in FIG. 7B, after the removal of portions of S/D 10, the top surface of the opening in S/D 10 is below at least the bottom surface of the top channel of channels 7 and above the top surface of the middle channel.

The isotropic etch of S/D 10 enlarges the opening or trench in semiconductor structure 700B and forms a larger dome-like opening where the bottom surface of S/D 10 is gouged or removed forming an upside down-like crater-like shape where a circular crescent-like portion of the bottom of S/D 10 can be removed. After removing the crescent-like bottom portion of S/D 10, the bottom surface of S/D 10 has a rounded surface creating an upside down u-shaped bottom surface. The isotropic etch also removes a similar amount or portion of S/D 10 from vertical sides until the opening in S/D 10 contacts at least the bottom channel of channels 7. The opening in S/D 10 can have vertical sidewalls adjacent to and contacting the bottom inner spacer 8 and the bottom channel of channels 7. In FIG. 7B, a larger circular or crescent-like portion of the bottom of S/D 10 is removed compared to the removed portion of S/D 10 depicted in FIG. 6B.

In FIG. 7B, the isotropic etch stops when the sidewall of the bottom channels adjacent to the removed S/D 10 are exposed and before the opening in S/D 10 extends to a level of the bottom of the second or middle channel of channels 7. In other examples, the opening in S/D 10 may extend to another channel of channels 7 (e.g., the opening of the etched S/D 10 extends to expose the middle channel and may extend to or be lower than the top surface of the top channel of channels 7).

In various embodiments, after completing the isotropic etching of S/D 10, a lateral etch of the exposed bottom channel of channels 7 occurs. The lateral etch of the bottom channel can recess the outer edges of the bottom channel (e.g., composed of silicon). The recess of the bottom channel extends horizontally until stopping at an area where the remaining portion of the bottom channel is under a portion of gate 13. The lateral etching process, which can be a precisely controlled RIE, for example, removes exposed portions of the bottom channels of channels 7 on both sides of the opening or recess in S/D 10. As depicted in FIG. 7B, both of the exposed edges of the bottom channels on either side of the opening in S/D 10 are laterally removed until reaching a horizontal distance that is the horizontal distance to one or more adjacent gate 13 (i.e., the horizontal distance from the exposed sidewall of the bottom inner spacer 8 to the sidewall of the portion of gate 13 directly abutting the other sidewall of the bottom inner spacer 8).

In various embodiments, the outside edges of the bottom channels of channels 7 (e.g., under one of inner spacers 8 and above the bottom inner spacer 8) are exposed by the removed portion of the S/D 10 and are removed by the lateral etching process. After the lateral etching process, a center portion of the bottom channel of channels 7 remains between portions of gate 13 on either side of the removed portions of S/D 10. The remaining portion of the bottom channel contacts a sidewall of an adjacent S/D 10 that is not removed by the etching processes (e.g., depicted above and protected by protection layer 1 of the remaining placeholder 6). In other examples, the outside edge of more channels than the bottom channel of channels 7 may be exposed. In other words, in some cases, the outside edge of the bottom channel and the middle channel of channels 7 may be exposed to the lateral etching process.

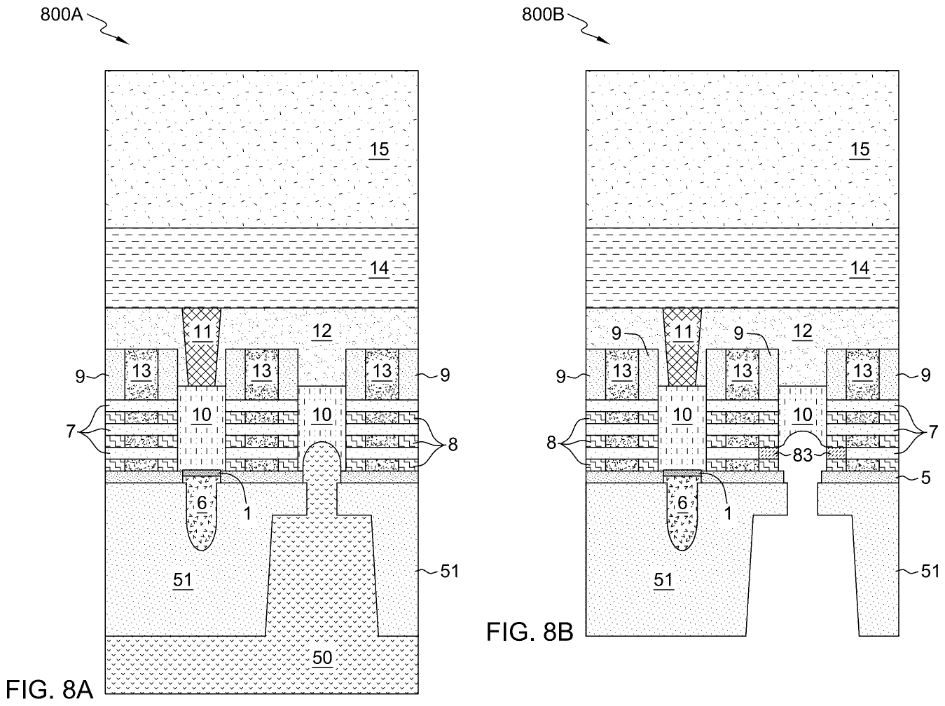

FIGS. 8A and 8B depict cross-sectional views of the semiconductor structures after depositing dielectric material, in accordance with an embodiment of the present invention.

As depicted, FIG. 8A is the cross-sectional view X1-X1 of semiconductor structure 800A. Semiconductor structure 800A is unchanged from semiconductor structure 700A depicted in FIG. 7A. As depicted, FIG. 8A is the same as FIG. 7A and includes all of the elements of FIG. 7A.

As depicted, FIG. 8B is the cross-sectional view X2-X2 of semiconductor structure 800B after depositing dielectric material 83 in the cavity created by the removal of the edge portions of the bottom channels of channels 7. As depicted, FIG. 8B includes the elements of semiconductor structure 700B with dielectric material 83.

In various embodiments, the deposition of dielectric material 83 occurs in the region where the bottom channel of channels 7 resided prior to the lateral etching of the bottom channel. In other words, dielectric material 83 replaces the removed portions of the bottom channel of channels 7 on either side of a portion of the removed S/D 10. As depicted, dielectric material 83 directly contacts a remaining portion of the bottom channels of channels 7 adjacent to the removed portion of S/D 10. Dielectric material 83 extends horizontally from the opening created during the removal of the portions of S/D 10 to the remaining portion of the bottom channel of channels 7. As depicted, dielectric material 83 deposits in the area of the removed portions of at bottom channel of channels 7 on either side of the opening created by the removal of a bottom portion of at least one of S/D 10.

The remaining portions of the bottom channels of channels 7 contacting dielectric material 83 are vertically located between portions of two of gate 13 that are on either side of the removed portions of S/D 10 and the bottom channels. For example, using a known deposition process (e.g., ALD, PVD, or CVD), dielectric material 83 is deposited in the opening between the bottom inner spacer 8 and the inner spacer 8 above the bottom inner spacer 8. The opening was created by the removal of portions of the bottom channel of channels 7.

The deposition of dielectric material 83 pinches off to stop at the opening where S/D 10 was removed in earlier process steps (e.g., depicted in FIG. 7B). Dielectric material 83 can be any suitable dielectric material. In various embodiments, dielectric material 83 is a nitride dielectric material (e.g., SiN). In FIG. 8B, dielectric material 83 does not directly contact S/D 10.

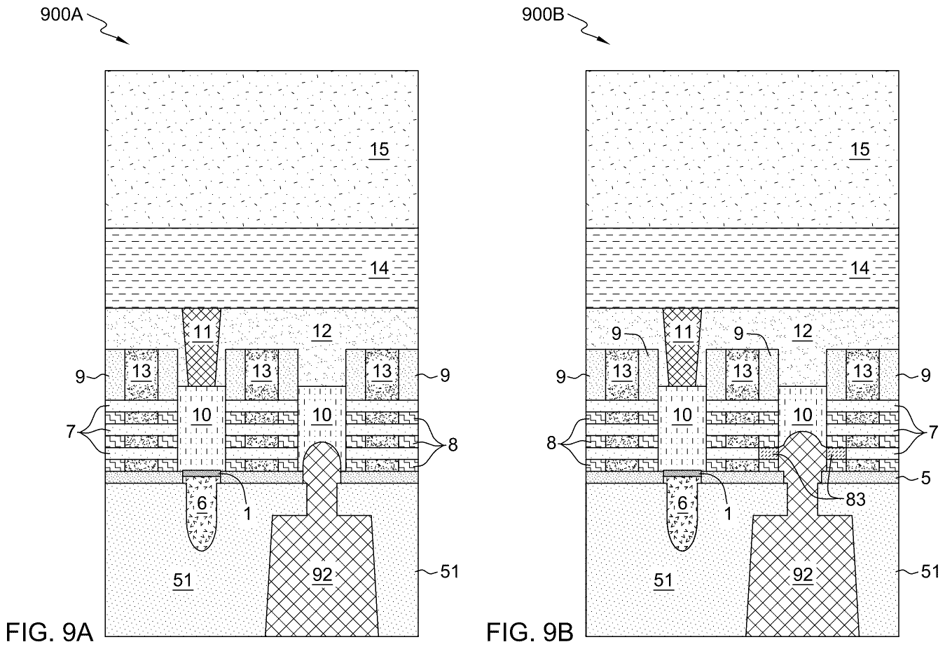

FIGS. 9A and 9B depict cross-sectional views of the semiconductor structures after removing OPL 50 and forming backside contact 92, in accordance with an embodiment of the present invention. As depicted, FIG. 9A includes all of the elements of semiconductor structure 900A without OPL 50 and with backside contact 92. As depicted, FIG. 9B includes all of the elements of semiconductor structure 800B with backside contact 92.

Semiconductor structure 900A includes BILD 51 with one of placeholders 6 under and contacting protective layer 1, one of S/D 10 resides on protective layer 1 and placeholder 6, BDI 5 on BILD 51, gate 13 with gate spacer 9 and inner spacers 8 on BDI 5, channels 7, a portion of second S/D 10 remains residing on backside contact 92. In FIG. 900A, channels 7 and inner spacers 8 contact the sidewalls of S/D 10. Semiconductor structure 900A also includes contact 11 connecting to one of S/D 10 to frontside interconnect wiring 14 on ILD 12. Also, as depicted in FIG. 900A, carrier wafer 15 bonds to frontside interconnect wiring 14.

In various embodiments, OPL 50 is removed in FIG. 9A, for example, using an OPL ash process. The removal of OPL 50 exposes portions of S/D 10, BDI 5, and BILD 51. Using known semiconductor contact formation processes such as contact metal deposition (e.g., W or Co) followed by a CMP to remove the excess contact metal and planarize the contact metal and BILD surfaces, backside contact 92 can be formed.

In semiconductor structure 900A, the contact metal of backside contact 92 contacts S/D 10, BDI 5, and BILD 51. Semiconductor structure 900A forms a high-performance GAA FET where S/D 10 contacts each of channels 7 (i.e., all three of channels 7 contact the rightmost S/D 10). As depicted in FIG. 9A, each of channels 7 contact S/D 10 and each of S/D 10 connects to one of a frontside contact 11 or backside contact 92. Backside contact 92 can have a rounded top surface. In FIG. 9A, backside contact 92 does not contact inner spacers 8, dielectric material 83, or any of channels 7. In some cases (not depicted), backside contact 92 contacts the bottom inner spacer 8 and the bottom channels of channels 7 (e.g., backside contact 92 may contact the two bottom inner spacers 8 and the bottom channels on either side of backside contact 92).

Semiconductor structure 900B includes BILD 51 with one of placeholders 6 under protective layer 1, backside contact 92, BDI 5 on BILD 51, gate 13 with gate spacers 9 and inner spacers 8 on BDI 5, one of S/D 10 resides on protective layer 1, a second S/D 10, channels 7, ILD 12, frontside interconnect wiring 14, and carrier wafer 15. The second or rightmost S/D 10 resides on backside contact 92 contacting with the top two channels of channels 7, dielectric material 83, and a bottom portion of gate spacers 9. In various embodiments, the second S/D 10 contacts at least a sidewall of each of the bottom inner spacers 8 and a sidewall of dielectric material 83. In some embodiments, the second S/D 10 contacts at least the middle channel, the bottom channel of channels 7, along with the bottom two inner spacers 8 of two adjacent gates 13. Contact 11 connects frontside interconnect wiring 14 in ILD 12 to the leftmost S/D 10 residing on protective layer 1 above placeholder 6. Frontside interconnect wiring 14 bonds to carrier wafer 15.

After forming backside contacts 92 in semiconductor structure 900B, the remaining portion of S/D 10 directly contacts each channel of channels 7 that are not electrically isolated from the second or rightmost S/D 10 by dielectric material 83. As depicted in semiconductor structure 900B of the low-power GAA FET, the contact metal of backside contact 92 directly contacts at least S/D 10, dielectric material 83, the bottom inner spacer 8, BDI 5, and BILD 51. In FIG. 9B, backside contact 92 extends up at least the top surface of the bottom channel but not beyond the top surface of the middle channel.

In various embodiments, backside contact 92 in FIG. 9B can be wider than backside contact 92 in FIG. 9A. As depicted in FIGS. 9A and 9B, the top surface of backside contact 92 has a rounded top surface. Backside contact 92 in FIG. 9B does not electrically connect to the bottom channel of channels 7. Dielectric material 83 electrically isolates backside contact 92 from the remaining portion of the bottom channel. As previously discussed, using the methods described with respect to FIGS. 1A and 1B through FIGS. 9A and 9B, respectively, a low-power semiconductor device, such as a low-power nanosheet GAA FET, can be formed without S/D 10 or backside contact 92 contacting all of channels 7 in the semiconductor device.

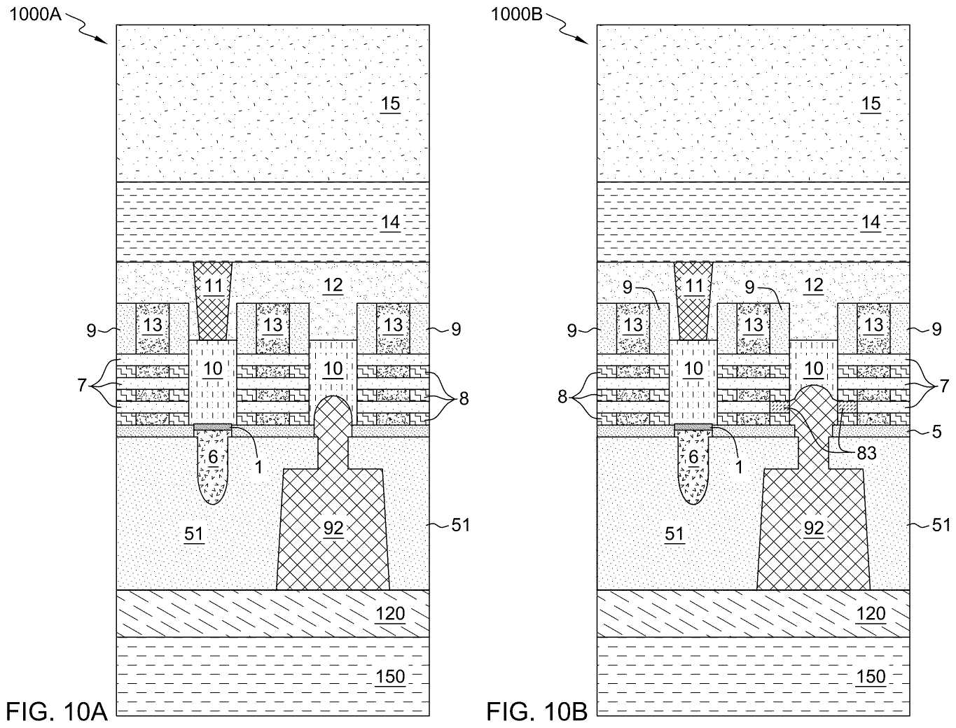

In this way, semiconductor structure 900B connects to fewer of channels 7 to S/D 10. One or more of channels 7 can be electrically isolated by dielectric material 83 from contacting S/D 10. In various embodiments, S/D 10 contacts backside contact 92, dielectric material 83, at least one of inner spacers 8, and one or more of channels 7. Reducing the connections of S/D 10 and backside contact 92 with channels 7 de-populates the number of active channels in the semiconductor device. The resulting semiconductor device formed later in FIG. 10B can be a lower power semiconductor device such as a low-power GAA FET (e.g., a nanosheet low-power GAA FET).

In another example (not depicted in FIG. 9B), backside contact 92 extends up to at least the top surface of the middle channel of channels 7 but not above the top surface of the top channel of channels 7. In this example, backside contact 92 in FIG. 9B may contact more than one of inner spacers 8 and contact dielectric material 83. In this example, the outside edges of the bottom and middle channel of channels 7 may be removed by the lateral etching process. Dielectric material 83 may then, be deposited in the removed outer portion of the bottom two channels of channels 7. In this example, backside contact 92 contacts at least the sidewalls of the bottom two of inner spacers 8 that are adjacent to (e.g., above and below the removed channels 7), the sidewalls of the two portions dielectric material 83 replacing the middle and bottom channels of channels 7, and S/D 10. With outer portions of both the bottom channel and the middle channel of channels 7 can be removed so that backside contact 92 contacts two portions of dielectric material 83, backside contact 92. In this example, the rightmost S/D 10 and backside contact 92 do not electrically connect to the middle and bottom channels of channels 7. The low-power nanosheet GAA FETs created in this example when complete would have a lower power than the nanosheet GAA FETs depicted in FIG. 9B (e.g., the right S/D 10 contacts only one of channels 7) when completed as depicted in FIG. 10B.

FIGS. 10A and 10B depict a cross-sectional view of semiconductor structures 1000A and 1000B after depositing BPR 120 and backside interconnect wiring 150, in accordance with an embodiment of the present invention. As depicted, FIGS. 10A and 10B include the elements of semiconductor structures 900A and 900B, respectively, with the addition of BPR 120 and backside interconnect wiring 150.

Using known semiconductor deposition processes such as but not limited to CVD, ALD, or PVD, a layer of a conductive metal (e.g., copper) can be deposited on BILD 51 and backside contact 92, as depicted in FIGS. 10A and 10B forming BPR 120.

After forming BPR 120, using known back-end-of-line (BEOL) semiconductor processes, backside interconnect wiring 150 can be formed on BPR 120. Semiconductor structure 1000A can form a high-performance semiconductor device (e.g., a high-performance nanosheet GAA FET). Semiconductor structure 1000A provides electrical connections between backside contact 92 and S/D 10 and each of channels 7. The high-performance semiconductor device depicted in FIG. 10A includes three nanosheet GAA FETs. The high-performance nanosheet GAA FETs each include an electrical connection to three active nanosheet channels by the rightmost S/D 10. As depicted in FIG. 10A, both of S/D 10 contact all three of channels 7. The rightmost S/D 10 contacts backside contact 92 and leftmost S/D 10 connects to frontside interconnect wiring 14 through contact 11.

Semiconductor structure 1000B can form a low-power semiconductor device (e.g., a low-power nanosheet GAA FET). As depicted in FIG. 10B, the rightmost S/D 10 connects to the middle channel and the top channel of channels 7. The rightmost nanosheet GAA FET of the three nanosheet GAA FETs depicted in FIG. 10B is a two nanosheet GAA FET. The rightmost S/D 10 contacting only two of channels 7 removes or de-populates the connection to the bottom channel of channels 7 (e.g., due to the addition of dielectric material 83). The low-power nanosheet GAA FET of FIG. 10B has a lower performance the high-performance GAA FET depicted in FIG. 10A. As previously discussed in another example (not depicted in FIG. 10B), using the method depicted in FIG. 1A through FIG. 10B, a lower power nanosheet GAA FET can be formed when a smaller number of nanosheet channels connect electrically to the source/drain and the backside interconnect wiring. In various embodiments, at least the bottom nanosheet channel (i.e., the bottom channel of channels 7) is disconnected from S/D 10, backside contact 92, and BPR 120 by dielectric material 83 for the electrical isolation of at least one nanosheet channel in the lower power nanosheet GAA FET.

In other embodiments, the nanosheet GAA FET of FIG. 10B has n channels where any number of channels less than or equal to n−1 channels are electrically isolated from backside contact 92 (e.g., n−1, n−2, or n−3 channels when n=4).

Semiconductor structure 1000B, as depicted, provides an electrical connection between S/D 10 and two of channels 7 where S/D 10 contacts backside contact 92. Semiconductor structure 1000B does not provide an electrical connection of S/D 10 or backside contact 92 to at least the bottom channel of channels 7. As previously described, dielectric material 83 forms a dielectric spacer electrically isolating the bottom channel from backside contact 92. The rightmost S/D 10 electrically connects with the middle and top channel of channels 7 on either side of S/D 10. Reducing the electrical connections with one or more of channels 7 to backside contact 92 and S/D 10 to BPR 120 and backside interconnect wiring 150 can reduce the power requirements of the resulting semiconductor device.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the invention. The terminology used herein was chosen to best explain the principles of the embodiment, the practical application or technical improvement over technologies found in the marketplace, or to enable others of ordinary skill in the art to understand the embodiments disclosed herein.

What is claimed is:

1. A semiconductor device comprising:
a dielectric material contacting a backside contact and at least one channel of a nanosheet field-effect transistor, wherein the dielectric material is between the at least one channel and the backside contact.

2. The semiconductor device of claim 1, wherein the backside contact extends above a top surface of a bottom channel of the field-effect transistor.

3. The semiconductor device of claim 1, wherein the backside contact is directly under and contacts a source/drain.

4. The semiconductor device of claim 3, wherein the source/drain directly contacts each channel that is not electrically isolated from the backside contact by the dielectric material.

5. The semiconductor device of claim 3, wherein the source/drain has vertical sidewalls and a rounded bottom surface, wherein the rounded bottom surface has an upside-down u-shape.

6. The semiconductor device of claim 1, wherein the backside contact resides on a backside power rails above one or more layers of backside interconnect wiring.

7. The semiconductor device of claim 1, wherein the semiconductor device is a low-power nanosheet gate-all-around field-effect transistor.

8. The semiconductor device of claim 1, wherein the dielectric material contacts sidewalls of the backside contact, sidewalls of at least a bottom channel, a top surface of at least of a bottom inner spacer of a gate, and a bottom surface of at least an inner spacer above the at least bottom inner spacer of the gate.

9. A semiconductor structure of a semiconductor chip comprising:
a low-power nanosheet gate-all-around field-effect transistor with a backside contact electrically isolated from at least one channel of a plurality of nanosheet channels; and
a high-performance nanosheet gate-all-around field-effect transistor with a source/drain contacting each of the plurality of nanosheet channels.

10. The semiconductor structure of claim 9, wherein the low-power nanosheet gate-all-around field semiconductor device includes a dielectric material between at least one bottom channel and the backside contact, and wherein the backside contact has a rounded top surface contacting a source/drain of the low-power nanosheet gate-all-around field-effect.

11. The semiconductor structure claim 9, wherein the low-power nanosheet gate-all-around field-effect transistor has the source/drain contacting at least one channel of the plurality of channels.

12. The semiconductor structure of claim 9, wherein the high-performance nanosheet gate-all-around field-effect transistor includes a backside contact contacting the source/drain, wherein the backside contact contacts a backside power rail, a bottom interlayer dielectric, a bottom dielectric isolation, and the source/drain.

13. The semiconductor structure of claim 12, wherein the source/drain contacts each channel of the high-performance nanosheet gate-all-around field-effect transistor.

14. The semiconductor structure of claim 9, wherein the low-power nanosheet gate-all-around field-effect transistor and the high-performance nanosheet gate-all-around field-effect transistor reside on a backside power rail in a semiconductor chip.

15. A method of forming a low-power semiconductor device comprising:
forming a portion of a nanosheet gate-all-around transistor with a carrier wafer bonded to frontside interconnect wiring and a bottom dielectric layer contacting a backside interlayer dielectric material with a placeholder in the backside interlayer dielectric layer;
removing a portion of backside interlayer dielectric around a portion of the placeholder;
removing the placeholder, wherein removing the placeholder includes removing a portion of a source/drain contacting the placeholder;
performing an isotropic etch of exposed portions of the source/drain, where the isotropic etch exposes a sidewall of at least one channel of a plurality of channels in the nanosheet gate-all-around transistor;
laterally etching a portion of the at least one channel, wherein the lateral etching extends horizontally to an area between portions of a gate structure of the nanosheet gate-all-around transistor;
depositing a dielectric material replacing the removed portion of the at least one channel; and
forming a backside contact, wherein the backside contact is electrically isolated from the at least one channel by the dielectric material replacing the removed portion of the at least one channel.

16. The method of claim 15, further comprising:
forming a backside power rail contacting the backside contact and the backside interlayer dielectric; and
forming one or more backside interconnect layers contacting the backside power rail.

17. The method of claim 15, wherein the source/drain connects to all channels of the plurality of channels except the at least one channel.

18. The method of claim 15, wherein the dielectric material electrically isolates the at least one channel from the backside contact and the source/drain.

19. The method of claim 15, wherein forming the backside contact further comprises:
a dome-shaped top surface of the backside contact connecting to the source/drain; and
sidewalls of the backside contact contacting at least the backside interlayer dielectric material, a bottom dielectric isolation, at least one inner spacer of the gate structure, and the at least one channel.

20. The method of claim 19, further comprises forming a low-power nanosheet gate-all-around transistor with the at least one channel electrically isolated from the backside contact and the source/drain.
